(19) United States
(12) Patent Application Publication
(10) Pub. No.: US 2008/0134974 A1
(43) Pub. Date: Jun. 12, 2008

(54) PLASMA PROCESSING APPARATUS AND GAS THROUGH PLATE

(75) Inventors: Tetsuro TAKAHASHI, Nirasaki-shi (JP); Koji Maekawa, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/025,428

(22) Filed: Feb. 4, 2008

Related U.S. Application Data
(63) Continuation-in-part of application No. PCT/JP2006/315273, filed on Aug. 2, 2006.

(30) Foreign Application Priority Data
Aug. 4, 2005 (JP) 2005-227159

(51) Int. Cl. C23C 16/00

(52) U.S. Cl. 118/715

(57) ABSTRACT

A plasma processing apparatus generates plasma of a processing gas in a processing chamber and performs plasma processing on a substrate. The plasma processing apparatus is provided with a gas through plate between a plasma generating region which corresponds to the substrate on the susceptor and an external region of such region. The through hole forming region is provided with a first region which corresponds to a center portion of the substrate; a second region arranged on an outer circumference of the first region; and a third region which is arranged on an outer circumference of the second region and includes an external region of the substrate. The diameter of a through hole in the first region is the smallest, and that of a through hole in the third region is the largest.

This application is a Continuation-in-Part Application of PCT International Application No. PCT/JP2006/315273 filed on 2 Aug. 2006, which designated the United States.

### FIELD OF THE INVENTION

The present invention relates to a plasma processing apparatus for performing a specific process, e.g., a nitridation process, an oxidation process or the like, on a target substrate, e.g., a semiconductor substrate and the like, by using a plasma, and a gas through plate used therefor.

### BACKGROUND OF THE INVENTION

A plasma processing is an essential technique necessary to manufacture semiconductor devices. Due to a recent trend for high integration and high speed of an LSI (Large Scale IC), design rules of semiconductor devices forming the LSI are miniaturized, and a semiconductor wafer is scaled up. Therefore, a plasma processing apparatus needs to cope with the above miniaturization and scaling up.

However, in the case of a parallel plate type plasma processing apparatus or an inductively coupled plasma processing apparatus which has been conventionally widely used, high electron temperature has frequently caused plasma damage on fine devices and has restricted high electron temperature, and a high-density plasma regions narrowly. Therefore, it is difficult to perform the plasma processing on a scaled-up semiconductor wafer uniformly at high speed.

Accordingly, it is natural that an RLSA (Radial Line Slot Antenna) microwave plasma processing apparatus capable of uniformly forming a plasma of a high density with a low electron temperature (see, e.g., Patent Document 1) has been widely noticed.

In the RLSA microwave plasma processing apparatus, an upper portion of a chamber is provided with a planar antenna having a plurality of slots formed in a predetermined pattern, and a microwave transmitted from a microwave generating source is radiated through the slots of the RLSA into the chamber maintained in a vacuum state. Next, a gas introduced into the chamber is converted into a plasma by a microwave electric field and, then, a target substrate such as a semiconductor wafer or the like is treated by the plasma.

In the RLSA microwave plasma processing apparatus, a plasma of high density can be realized over a wide region directly under the antenna and the plasma processing can be carried out uniformly in a short period of time. Moreover, the plasma of a low electron temperature is generated, so that damages to an under layer are reduced. Therefore, it is considered as a potential candidate to be employed in a nitridation process or an oxidation process of a silicon substrate which suffers from damages to the base.

In addition, there is proposed a technique for suppressing ion energy by providing a gas through plate having a plurality of through holes between a plasma generating section and a susceptor to thereby reduce damages with the use of the RLSA microwave plasma processing apparatus (see, e.g., Patent Document 2).

The Patent Document 2 discloses, as the gas through plate, a quartz plate having through holes formed uniformly therein.

However, despite the presence of the through holes that are uniformly formed in the gas through plate, the processing using a plasma of a process gas is not uniformly performed on the substrate by the effects of an antenna structure, a gas type, a pressure and the like, so that in-plane uniformity of the substrate in the processing is deteriorated. In the Patent Document 2, as a solution to overcome the non-uniformity, the amount of gas supplied to a central portion of the gas through plate is decreased by reducing diameters of the through holes formed at the central portion. However, it is not sufficient to overcome the non-uniformity. Especially, as a diameter of a wafer is scaled up to about 300 mm and further to about 450 mm, the non-uniformity of the processing becomes apparent. Although the same process is carried out on a glass substrate for manufacturing a liquid crystal display (LCD), the non-uniformity of the processing becomes more apparent in a case of a considerably large glass substrate which has a side of about 2 m in size.

Patent Document 1: Japanese Patent Laid-open Application No. 2000-294550

Patent Document 2: International Publication WO2004/047157

### SUMMARY OF THE INVENTION

In view of the above, the present invention provides a plasma processing apparatus capable of achieving required in-plane uniformity of a substrate in a plasma processing by providing a gas through plate between a plasma generating section and a substrate support for supporting a target substrate in a vacuum chamber, and a gas through plate used in the plasma processing apparatus.

In accordance with a first aspect of the present invention, there is provided a plasma processing apparatus including: an evacuable vacuum processing chamber for processing a target substrate; a process gas introducing mechanism for introducing a process gas into the processing chamber; a plasma generating mechanism for generating a plasma of the process gas in the processing chamber; a substrate supporting table for supporting the target substrate in the processing chamber; and a gas through plate, provided between a plasma generating section and the substrate supporting table in the processing chamber, having a plurality of through holes for passing the plasma of the process gas therethrough, wherein in the gas through plate, a through hole forming region in which the through holes are formed includes a region corresponding to the target substrate on the substrate supporting table and an external region thereof, and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of regions having the through holes of a different diameter.

In accordance with a second aspect of the present invention, there is provided a plasma processing apparatus including: an evacuable vacuum processing chamber for processing a target substrate; a process gas introduction mechanism for introducing a process gas into the processing chamber; a plasma generating mechanism for generating a plasma of the process gas in the processing chamber; a substrate supporting table for supporting the target substrate in the processing chamber; and a gas through plate, provided between a plasma generating section and the substrate supporting table in the processing chamber, having a plurality of through holes for passing the plasma of the process gas therethrough, wherein in the gas through plate, a through hole forming region in which the through holes are formed includes a region corresponding to the target substrate on the substrate supporting table and an external region thereof, and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of the regions having the through holes of a different opening ratio, and wherein the through holes in the first region have a smallest opening ratio while the through holes in the third region have a largest opening ratio.

In accordance with a third aspect of a gas through plate having a plurality of through holes for passing a plasma of a process gas therethrough, the gas through plate being provided between a plasma generating section and a substrate supporting table in a processing chamber of a plasma processing apparatus that performs a plasma processing on a target substrate supported on the substrate supporting table by using the plasma of the process gas generated in the processing chamber, wherein a through hole forming region in which the through holes are formed includes a region corresponding to the target substrate on the substrate supporting table and an external region thereof, and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of the regions having the through holes of a different opening ratio, and wherein the through holes in the first region have a smallest opening ratio while the through holes in the third region have a largest opening ratio.

In accordance with the first aspect, preferably, wherein a distance between the substrate supporting table and the gas through plate is in a range of from 3 to 20 mm, and a ratio of an opening ratio of the through holes in the first region, that of the through holes in the second region and that of the through holes in the third region is 1:1-2.6:1.1-3.2.

Preferably, a boundary between the second region and the third region corresponds to an outer periphery of the target substrate supported on the substrate supporting table. Further, when a diameter of the target substrate is set to 1, a diameter of the through hole forming region may range from about 1.1 to 2.0.

In accordance with the second and third aspects, preferably, a distance between the substrate supporting table and the gas through plate is in a range of from 3 to 20 mm, and the opening ratio of the through holes in the first region ranges from about 25 to 55%; the opening ratio of the through holes in the second region ranges from about 30 to 65%; and the opening ratio of the through holes in the third region ranges from about 50 to 80%.

Preferably, a boundary between the second region and the third region corresponds to an outer periphery of the target substrate supported on the substrate supporting table. Further, when a diameter of the target substrate is set to 1, a diameter of the through hole forming region may range from about 1.1 to 2.0.

In accordance with the first and second aspects, preferably, the plasma generating mechanism includes a microwave generating source; a planar antenna provided at an upper portion of the processing chamber, for radiating a microwave into the processing chamber; and a waveguide for transmitting the microwave from the microwave generating source to the planar antenna.

In accordance with the first to third aspects, preferably, N concentration of 20 atomic % is introduced into an oxide film with a uniformity of 3% (1σ).

Further, the gas through plate may be made of a high purity quartz having impurities of about 50 ppm or less.

In accordance with the first aspect of the present invention, a gas through plate, wherein a through hole forming region in which the through holes are formed includes a region corresponding to the target substrate on the substrate supporting table and an external region thereof, is used as the gas through plate. Further, the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, and wherein the through holes in the first region have a smallest diameter while the through holes in the third region have a largest diameter. Therefore, it is possible to effectively suppress a concentrated supply of the plasma of the process gas to the central portion of the target substrate, and also possible to improve a non-uniform supply of the process gas to the peripheral portion thereof. As a result, it is possible to achieve the required in-plane uniformity of the plasma processing by using the plasma of the process gas.

Further, in accordance with the second and third aspects of the present invention, a gas through plate, wherein a through hole forming region in which the through holes are formed includes a region corresponding to the target substrate on the substrate supporting table and an external region thereof, is used as the gas through plate. Further, the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, and wherein the through holes in the first region have a smallest opening ratio while the through holes in the third region have a largest opening ratio. Hence, it is possible to achieve the required in-plane uniformity of the plasma processing by using the plasma of the process gas.

### BRIEF DESCRIPTION OF THE DRAWINGS

FIG. 1 is a schematic cross sectional view of a plasma processing apparatus in accordance with an embodiment of the present invention;

FIG. 2 shows another attachment method of a gas through plate;

FIG. 3 describes a planar antenna used in the plasma processing apparatus in FIG. 1;

FIG. 4 presents a top view of the gas through plate used in the plasma processing apparatus of FIG. 1;

FIG. 5 shows a cross sectional view of the gas through plate used in the plasma processing apparatus in FIG. 1;

FIG. 6 provides a top view of a gas through plate in accordance with a Comparative Example 1;

FIG. 7 offers a top view of a gas through plate in accordance with a Comparative Example 2;

FIG. 8A depicts a distribution of the N dose in the case of using a gas through plate of a Test Example;

FIG. 8B illustrates a distribution of the N dose in the case of using the gas through plate of the Comparative Example 1; and

FIG. 8C shows a distribution of the N dose in the case of using the gas through plate of the Comparative Example 2.

### DETAILED DESCRIPTION OF THE EMBODIMENT

The embodiments of the present invention will be described in detail with reference to the accompanying drawings which form a part hereof.

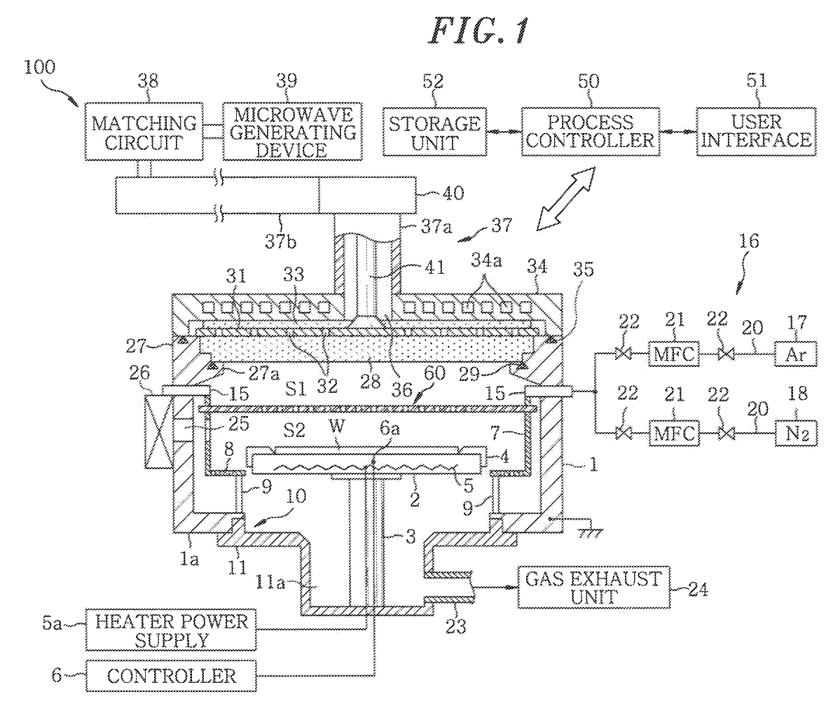

FIG. 1 is a schematic cross sectional view of a plasma processing apparatus 100 in accordance with a first embodiment of the present invention. The plasma processing apparatus 100 is configured as an RLSA (radial line slot antenna) microwave plasma processing apparatus capable of generating a microwave plasma of a high density and a low electron temperature by introducing microwaves into a processing chamber by using a planar antenna having a plurality of slots, particularly an RLSA. In the embodiment of the present invention, the plasma processing apparatus 100 is applied to, e.g., a nitridation process of a gate insulating film such as a MOS transistor or the like.

The plasma processing apparatus 100 includes a substantially cylindrical airtight chamber 1 that is grounded. A circular opening 10 is formed at a substantially central portion of a bottom wall 1a of the chamber 1. Further, an exhaust chamber 11 projecting downward is provided on the bottom wall 1a while communicating with the opening 10.

A susceptor 2 made of ceramic, e.g., AlN or the like, is provided in the chamber 1 to horizontally support a wafer W as a target object. The susceptor 2 is supported by a cylindrical supporting member 3 extending upward from a central bottom portion of the exhaust chamber 11, the supporting member 3 being made of ceramic, e.g., AlN or the like. A guide ring 4 for guiding the wafer W is provided on an outer periphery portion of the susceptor 2. The guide ring 4 serves to protect the susceptor 2 and prevent contamination of foreign materials from the susceptor 2. Moreover, a resistance heater 5 is buried in the susceptor 2 to heat the susceptor 2 by a power supplied from a heater power supply 5a. The wafer W serving as a target object is heated by heat thus generated. Further, a thermocouple 6a is buried in the susceptor 2, so that a controller 6 can control the temperature of the susceptor 2 within a range between the room temperature and about 1000° C. based on a detected temperature signal from the thermocouple 6a. Besides, a cylindrical liner 7 made of, e.g., quartz, is provided on an inner periphery of the chamber 1. The liner 7 is divided into an upper part and a lower part by a gas through plate 60 to be described later. By providing the liner 7 made of quartz or the like, an inner space of the chamber 1 is preserved extremely cleanly by being protected from contamination by metal or alkaline elements and the like. Furthermore, an annular baffle plate 8 extending to a bottom portion of the liner 7 is provided at an outer peripheral portion of the susceptor 2 to thereby uniformly exhaust the inner space of the chamber 1. The baffle plate 8 is supported on the bottom wall of the chamber 1 by a plurality of support columns 9.

The susceptor 2 is provided with wafer supporting pins (not shown) for supporting and vertically moving the wafer W. The wafer supporting pins can be protruded from or retracted into the surface of the susceptor 2.

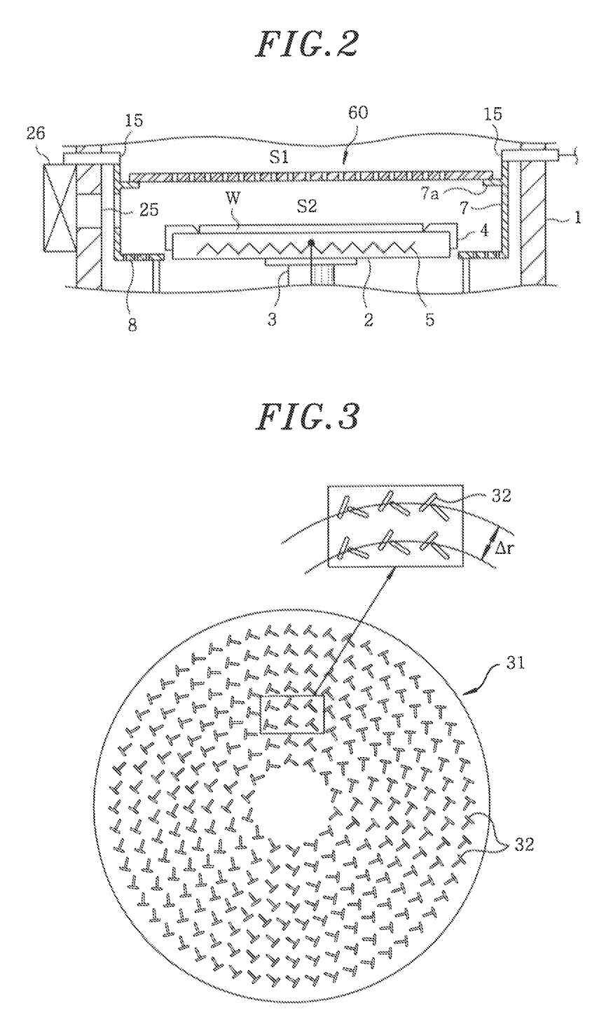

Disposed above the susceptor 2 is the gas through plate 60 having a plurality of through holes. The through holes allow a plasma of a process gas to pass therethrough in a state where energy of active species (ions, radicals or the like) in the plasma is reduced. The gas through plate 60 may be made of a dielectric material, e.g., ceramic such as quartz, sapphire, SiN, SiC, Al₂O₃ and the like, single crystalline silicon, polysilicon, amorphous silicon and the like. In the embodiment of the present invention, the plate 60 is made of quartz. In this case, the quartz may be a high purity material having impurities of about 50 ppm or less. The gas through plate 60 is fixed such that an outer peripheral portion thereof is attached to be inserted in the liner 7 that is vertically divided. As shown in FIG. 2, the gas through plate 60 may be attached to the liner 7 while being mounted on protrusions 7a provided at an inner periphery of the liner 7. A detailed description of the gas through plate 60 will be provided later.

An annular gas introducing member 15 is provided on a sidewall of the chamber 1, and a gas supply system 16 is connected thereto. The gas introducing member 15 may be disposed in the form of a shower shape. The gas supply system 16 includes, e.g., an Ar gas supply source 17 and an N₂ gas supply source 18, and these gases are supplied to the gas introducing member 15 through their respective gas lines 20, and then are introduced through the gas introducing member 15 into the chamber 1. Each of the gas lines 20 is provided with a mass flow controller 21 and opening/closing valves 22 disposed at an upstream and a downstream of the mass flow controller 21. Instead of the Ar gas, a rare gas such as Kr, Xe, He or the like can be used.

A gas exhaust line 23 is connected on a side surface of the exhaust chamber 11, and a gas exhaust unit 24 including a high speed vacuum pump is connected with the gas exhaust line 23. By operating the gas exhaust unit 24, a gas in the chamber 1 is uniformly discharged into a space 11a of the exhaust chamber 11 and then is exhausted through the gas exhaust line 23. Accordingly, the inner space of the chamber 1 can be depressurized to a predetermined vacuum level, e.g., about 0.133 Pa, at a high speed.

Provided on the sidewall of the chamber 1 are a loading/unloading port 25 for loading/unloading the wafer W between the chamber 1 and a transfer chamber (not shown) adjacent to the plasma processing apparatus 100 and a gate valve 26 for opening and closing the loading/unloading port 25.

An upper portion of the chamber 1 has an opening, and an annular support portion 27 is provided along a peripheral portion of the opening. A transmitting plate 28 for transmitting a microwave is airtightly disposed on the support portion 27 via sealing members 29, the transmitting plate 28 being made of a dielectric material, e.g., ceramic such as quartz, Al₂O₃ or the like. Therefore, the inner space of the chamber 1 is airtightly maintained.

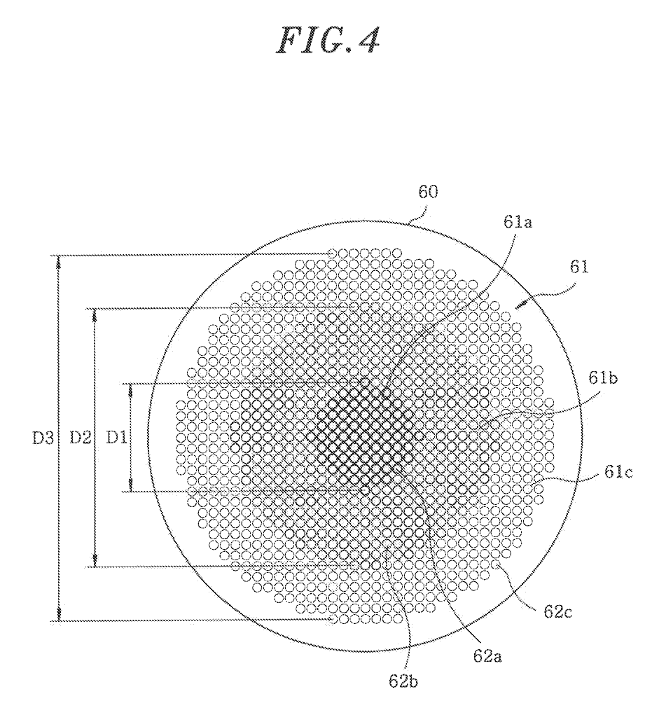

A disc-shaped planar antenna member 31 is provided on the transmitting plate 28 while facing the susceptor 2. The planar antenna member 31 is fixed to a top portion of the sidewall of the chamber 1. The planar antenna member 31 is made of, e.g., aluminum plate or copper plate coated with gold or silver, and has a plurality of slot holes 32 which are formed therethrough in a predetermined pattern for radiating microwave. The slot holes 32 are formed in, e.g., a long groove shape, as illustrated in FIG. 3. Typically, each of the adjacent slot holes 32 is disposed in a T shape. Further, the slot holes 32 are concentrically disposed. A length of the slot hole 32 or an arrangement interval therebetween is determined depending on a wavelength λg of the microwave.

For example, the slot holes 32 are spaced apart from each other at an interval of λg/4, λg/2 or λg. Referring to FIG. 3, the interval between the adjacent slot holes 32 that are concentrically disposed is indicated as Δr. The slot holes 32 may have another shape, e.g., a circular shape, a circular arc shape or the like. Further, the microwave radiation holes 32 can be arranged in another pattern, e.g., a spiral pattern, a radial pattern or the like, without being limited to the concentric circular pattern.

Provided on a top surface of the planar antenna member 31 is a retardation member 33 having a dielectric constant greater than that of a vacuum. The retardation member 33 is made of, e.g., ceramic such as quartz, Al₂O₃ or the like, fluorine-based resin such as polytetrafluoroethylene or the like, or polyimide-based resin. A wavelength of a microwave becomes longer in the vacuum. The retardation member 33 reduces the wavelength of the microwave, thereby being capable of adjusting a plasma. The planar antenna member 31 may be in contact with or separated from the transmitting plate 28 and the retardation member 33.

A shield lid 34 made of a metal material, e.g., aluminum, stainless steel or the like, is provided on a top surface of the chamber 1 to cover the planar antenna member 31 and the retardation member 33. The top surface of the chamber 1 and the shield lid 34 are sealed by sealing members 35. Cooling water paths 34a are formed in the shield lid 34, so that the shield lid 34, the retardation member 33, the planar antenna 31 and the transmitting plate 28 are cooled by circulating cooling water through the water paths 34a. As a consequence, the shield lid 34, the retardation member 33, the planar antenna member 31 and the transmitting plate 28 can be protected from deformation or damage. The shield lid 34 is grounded.

The shield lid 34 has an opening 36 at the center of a top wall thereof, and a waveguide 37 is connected with the opening. A microwave generating device 39 is connected with an end portion of the waveguide 37 via a matching circuit 38. Accordingly, a microwave having a frequency of, e.g., 2.45 GHz, which is generated from the microwave generating device 39, is propagated to the antenna member 31 via the waveguide 37. The microwave may have a frequency of 8.35 GHz, 1.98 GHz or the like.

The waveguide 37 includes a coaxial waveguide 37a having a circular cross section and extending upward from the opening 36 of the shield lid 34, and a rectangular waveguide 37b extending in a horizontal direction and connected with an upper portion of the coaxial waveguide 37a via a mode transducer 40. The mode transducer 40 between the rectangular waveguide 37b and the coaxial waveguide 37a has a function of converting a TE mode of the microwave propagating in the rectangular waveguide 37b into a TEM mode. An internal conductor 41 is extended from a center of the coaxial waveguide 37a, and a lower portion of the internal conductor 41 is fixedly connected to a center of the planar antenna member 31. Accordingly, the microwave is efficiently and uniformly propagated to the planar antenna member 31 via the internal conductor 41 of the coaxial waveguide 37a in a radial shape.

Each component of the plasma processing apparatus 100 is connected with a process controller 50 having a CPU and controlled by the process controller 50. The process controller 50 is connected with a user interface 51 having a keyboard, a display and the like. A process operator uses the keyboard when inputting commands for managing the plasma processing apparatus 100, and the display is used to display the operation status of the plasma processing apparatus 100.

Further, the process controller 50 is connected with a storage unit 52 for storing therein control programs (software) for implementing various processes in the plasma processing apparatus 100 under the control of the process controller 50, and recipes including processing condition data and the like.

If necessary, the process controller 50 executes a recipe read from the storage unit 52 in response to instructions from the user interface 51, thereby implementing a required process in the plasma processing apparatus 100 under the control of the process controller 50. Further, the recipes such as the control programs, the processing condition data and the like can be read from a computer-readable storage medium, e.g., a CD-ROM, a hard disk, a flexible disk, a flash memory or the like, or transmitted on-line from another device via, e.g., a dedicated line when necessary.

Hereinafter, the gas through plate 60 will be described more in detail.

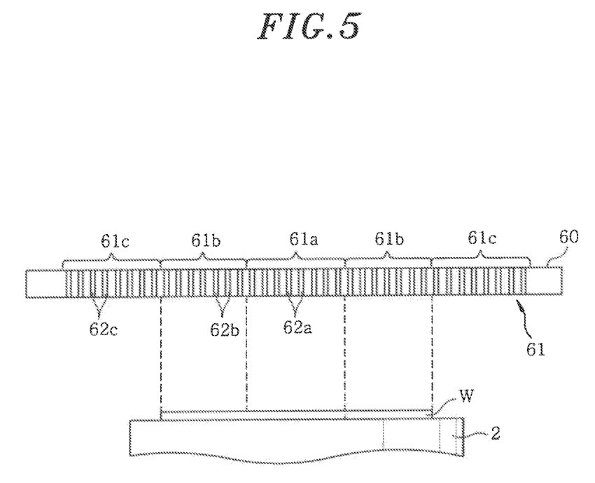

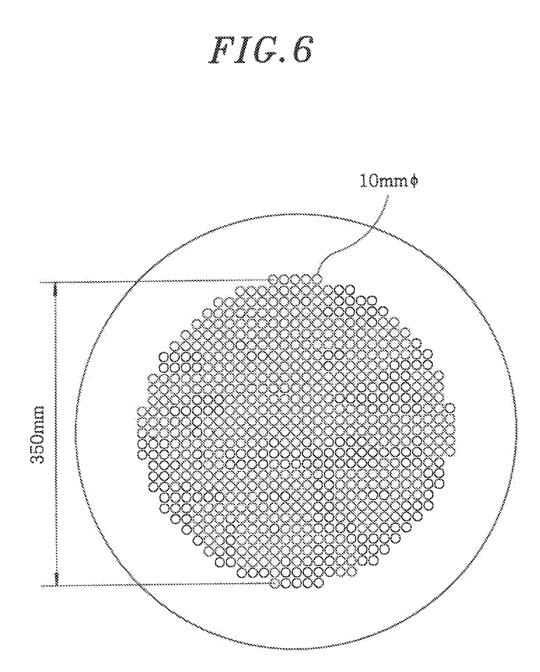

FIG. 4 presents a top view of the gas through plate 60, and FIG. 5 represents a cross sectional view thereof. In the gas through plate 60, a through hole forming region 61 formed with through holes includes a region corresponding to the wafer W supported on the susceptor 2 and an external region thereof. The through hole forming region 61 is provided with a first region 61a corresponding to a central portion of the wafer W; a second region 61b arranged at an outer circumference of the first region 61a to correspond to a peripheral portion of the wafer W; and a third region 61c arranged at an outer circumference of the second region 61b to include the external portion of the wafer W. Each of the regions 61a to 61c has the through holes of a different diameter. The first region 61a has through holes 62a of a smallest diameter; the third region 61c has through holes 62c of a largest diameter; and the second region 61b has through holes 62b of a diameter between the smaller and the largest diameter.

Here, the diameter of the through holes 62a in the first region 61a, that of the through holes 62b in the second region 61b and that of the through holes 62c in the third region 61c are preferably ranging from about 5 to 15 mm, and more preferably from about 7 to 12 mm. Further, a ratio of the diameter of the through holes 62a, that of the through holes 62b and that of the through holes 62c is preferably 1:1-1.2:1.1-1.4.

That is, the diameters of the through holes 62a, 62b and 62c are set to be increased in radial directions of the substrate in that order. Accordingly, it is possible to perform a plasma processing in which the substrate has in-plane uniformity by controlling the active species, such as radicals and the like passing through the through holes 62a, 62b and 62c. Especially, it is effective to improve in-plane uniformity of N concentration by introducing N of the plasma into an oxide film.

Further, an opening ratio (hole area/total area) of the through holes is also important. The through holes 62a in the first region 61a have a smallest opening ratio; the through holes 62c in the third region 61c have a largest opening ratio; and the through holes 62b in the second region 61b have an opening ratio between the smallest and the largest opening ratio. Namely, the opening ratio of the through holes 62a in the first region 61a is preferably in a range of from about 25 to 55%; that of the through holes 62b in the second region 61b is in a range of from about 30 to 65%; and that of the through holes 62c in the third region 61c is preferably in a range of from about 50 to about 80%. Moreover, a ratio of the opening ratio of the through holes 62a in the first region 61a, that of the through holes 62b in the second region 61b and that of the through holes 62c in the third region 61c is preferably 1:1-2.6:1.1-3.2.

That is, the opening ratio of the through holes 62a in the first region 61a, that of the through holes 62b in the second region 61b and that of the through holes 62c in the third region 61c are set to be increased in radial directions of the substrate in that order. Accordingly, it is possible to perform a plasma processing in which wafer has in-plane uniformity by controlling the active species, such as radicals and the like passing through the through holes 62a, 62b and 62c. Especially, it is effective to improve in-plane uniformity of N concentration by introducing N of the plasma into an oxide film.

A diameter D1 of the first region 61a, a diameter D2 of the second region 61b and a diameter D3 of the third region 61c may be appropriately determined. Preferably, the diameter D2 is substantially the same as that of the wafer W, as shown in FIG. 4. In other words, it is preferable that a boundary between the second region 61b and the third region 61c corresponds to the outer circumference of the wafer W supported on the susceptor 2. In case a diameter of the wafer W is set to 1, a diameter of the through hole forming region 61 ranges preferably from about 1.1 to 2.0, and more preferably from about 1.1 to 1.5.

For example, when the wafer W has a diameter of about 300 mm, the diameter of the through holes 62a in the first region 61a ranges preferably from about 7 to 11 mm; that of the through holes 62b in the second region 61b ranges from about 7 to 11 mm; and that of the through holes 62c in the third region 61c ranges preferably from about 9 to 13 mm. Further, the diameter D1 of the first region 61a ranges preferably from about 80 to 190 mm; the diameter D2 of the second region 61b ranges preferably from about 250 to 450 mm; and the diameter D3 of the third region 61c ranges preferably from about 400 to 650 mm. In a preferable typical example of the wafer having a diameter of about 300 mm, the diameter of the through holes 62a in the first region 61a, that of the through holes 62b and that of the through holes 62c are respectively about 9.5, 9.7 and 11 mm, and the diameter D1 of the first region 61a, the diameter D2 of the second region 61b and the diameter D3 of the third region 61c are respectively about 125, 300 and 425 mm.

That is, the respective diameters D1 to D3 of the through holes 62a to 62c are set to be increased in radial directions in that order. Accordingly, it is possible to perform a plasma processing in which wafer has in-plane uniformity by controlling the active species, such as radicals and the like passing through the through holes 62a, 62b and 62c. Especially, it is effective to improve in-plane uniformity of N concentration by introducing N of the plasma into an oxide film.

For example, when the wafer W has a diameter of about 300 mm, on the assumption that the diameters D1 to D3 of the first to the third region 61a to 61c range from about 80 to about 190 mm, from about 250 to 450 mm and from about 400 to 650 mm, respectively, an opening ratio of the through holes 62a in the first region 61a ranges preferably from about 25 to 55%; that of the through holes 62b in the second region 61b ranges preferably from about 30 to 65%; and that of the through holes 62c in the third region 61c ranges preferably from about 50 to 80%. In a preferable typical example of the wafer having a diameter of about 300 mm, the opening ratio of the through holes 62a in the first region 61a is about 42.2%; the opening ratio of the through holes 62b in the second region 61b is about 47.6%; and the opening ratio of the through holes 62c in the third region 61c is about 66.8%, and the diameter D1 of the first region 61a is about 125 mm; the diameter D2 of the second region 61b is about 300 mm; and the diameter D3 of the third region 61c is about 425 mm. At this time, a ratio of the opening ratio of the through holes 62a in the first region 61a, that of the through holes 62b in the second region 61b and that of the through holes in the third region 61c is 1:1.12:1.58. Accordingly, it is possible to perform a plasma processing in which wafer has in-plane uniformity by controlling the active species, such as radicals and the like passing through the through holes 62a, 62b and 62c. Especially, it is effective to improve in-plane uniformity of N concentration by introducing N of the plasma into an oxide film.

Preferably, the gas through plate 60 is attached near the wafer W. That is, a distance between a lower portion of the gas through plate 60 and the wafer W ranges preferably from about 3 to 20 mm, and more preferably about 10 mm. In this case, a distance between an upper end of the gas through plate 60 and a lower end of the transmitting plate 28 ranges preferably from about 20 to 50 mm.

As set forth above, the gas through plate 60 reduces the energy of active species (ions, radicals or the like) in the plasma of the process gas. By forming the gas through plate 60 with a dielectric material, mainly the radicals in the plasma are allowed to pass therethrough and it becomes possible to reduce the ion energy.

As the distance between the lower portion of gas through plate 60 and the wafer W is larger, the uniformity becomes fine, however, the processing time taken for uniformly introducing N into an oxide film at a desirable concentration becomes longer, whereby throughput is deteriorated. Further, the processing apparatus also becomes bigger, resulting in cost increase. However, by arranging the gas through plate in accordance with the embodiment of the present invention apart from the wafer W by a distance of from 3 to 20 mm, N is uniformly introduced into the oxide film at a high speed, whereby it is possible to provide the processing apparatus with a low cost.

In the RLSA type plasma processing apparatus 100 configured as described above, first of all, the gate valve 26 is opened. Next, the wafer W having a silicon layer is loaded into the chamber 1 through the loading/unloading port 25 and then is mounted on the susceptor 2. Thereafter, Ar gas and N₂ gas are introduced from the Ar gas supply source 17 and the N₂ gas supply source 18 of the gas supply system 16 into the chamber 1 through the gas introducing member 15 at predetermined flow rates, respectively.

Specifically, the flow rate of the rare gas such as Ar or the like and the flow rate of the N₂ gas are set to range from about 100 to 3000 mL/min (sccm) and from about 10 to 1000 mL/min (sccm), respectively. A processing pressure in the chamber is controlled to range from about 1.3 to 1333 Pa. The wafer W is heated to a temperature in a range from about 300 to 500° C.

Next, the microwave generated from the microwave generating device 39 is guided into the waveguide 37 via the matching circuit 38 wherein the microwave is supplied to the planar antenna member 31 via the rectangular waveguide 37b, the mode transducer 40, the coaxial wave guide 37a and the internal conductor 41 in that order. Thereafter, the microwave is radiated through the slots of the planar antenna member 31 into the chamber 1 via the transmitting plate 28. The microwave propagates in the rectangular waveguide 37b in the TE mode. The TE mode of the microwave is converted into the TEM mode in the mode converter 40, and the microwave propagates in the TEM mode through the coaxial waveguide 37a toward the planar antenna member 31. An electromagnetic field is formed in the chamber 1 by the microwave radiated from the planar antenna member 31 into the chamber 1 through the transmitting plate 28, thereby converting the Ar gas and the N₂ gas into a plasma. The silicon oxide film formed on the wafer W is nitrided by the nitrogen-containing plasma. At this time, the power of the microwave generating device 39 ranges preferably from about 0.5 to 5 kW, and more preferably from about 1 to 3 kW.

By radiating the microwave through the slot holes 32 of the planar antenna member 31, there is generated a plasma having a high density in a range from about 1×10¹⁰ to 5×10¹²/cm³ with a low electron temperature of about 1.5 eV or less in a region S1, about 1.0 eV or less in a region S2, and about 0.7 eV or less near the wafer W. Although the microwave plasma thus generated causes less plasma damage by ions or the like, the plasma damage can be greatly reduced by the presence of the gas through plate 60. Namely, when the plasma passes through the gas through holes of the gas through plate 60, the energy of the active species (ions or the like) in the plasma is reduced, whereby the active species can uniformly pass therethrough. Consequently, the plasma that has passed through the gas through plate 60 becomes milder, thereby further reducing the plasma damage to the wafer W. N can be introduced into the silicon oxide film formed on the wafer W at a uniform concentration by the action of the active species in the plasma, mainly by the action of nitrogen radicals N* or the like.

In a conventional gas through plate, through holes are uniformly disposed. In that case, the plasma is too strong near the central portion of the wafer W, and a high nitriding power in the central portion makes it difficult to perform a uniform nitridation process. Accordingly, there have been attempts to suppress the nitriding power in the central portion of the wafer by decreasing the amount of nitrogen gas (active nitrogen) supplied by reducing the diameter of the through holes of the gas through plate, the through holes being formed in the region corresponding to the central portion of the wafer. However, it was not sufficient to overcome the above drawback.

Therefore, in the present invention, the through hole forming region 61 of the gas through plate 60 includes a region corresponding to the wafer W supported on the susceptor 2 and an external region thereof, as set forth above. The through hole forming region 61 having through holes is provided with a first region 61a corresponding to a central portion of the wafer W; a second region 61b arranged on an outer circumference of the first region 61a to correspond to a peripheral portion of the wafer W; and a third region 61c arranged on an outer circumference of the second region 61b to include the outer portion of the wafer W. Each of the regions 61a to 61c has the through holes of a different diameter. The first region 61a has through holes 62a of a smallest diameter; the third region 61c has through holes 62c of a largest diameter; and the second region 61b has through holes 62b of a diameter between the smaller and the largest diameter.

With the above configuration, it is possible to effectively suppress a concentrated supply of a plasma of nitrogen gas (active nitrogen) to the central portion of the wafer W, and also possible to improve a non-uniform supply of the plasma of nitrogen gas (active nitrogen) to the peripheral portion thereof. As a result, the plasma processing using the nitrogen gas can be uniformly carried out on the entire surface of the wafer W with the N concentration of 3% (σ/Avg) or less.

To be specific, the diameter of the through holes 62a in the first region 61a, that of the through holes 62b in the second region 61b and that of the through holes 62c in the third region 61c range preferably from about 5 to 15 mm, and more preferably from about 7 to 12 mm. Further, a ratio of the diameter of the through holes 62a, the diameter of the through holes 62b and the diameter of the through holes 62c is set to 1:1-1.2:1.1-1.4. Accordingly, the effects of uniformly distributing the plasma of nitrogen gas (active nitrogen) with the N concentration of 3% (σ/2 Avg) or less can be further improved.

The uniformity of distribution of the plasma of nitrogen gas (active nitrogen) is also affected by the opening ratio of the through holes. The through holes 62a in the first region 61a have a smallest opening ratio; the through holes 62c in the third region 61c have a largest opening ratio; and the through holes 62b in the second region 61b have an opening ratio between the smallest and the largest opening ratio.

Specifically, the opening ratio of the through holes 62a in the first region 61a ranges preferably from about 25 to 55%; that of the through holes 62b in the second region 61b ranges preferably from about 30% to about 65%; and that of the through holes 62c in the third region 61c ranges preferably from about 50% to about 80%. By setting like this, it is possible to greatly improve the effects of uniformly distributing the plasma of nitrogen gas (active nitrogen) with the N concentration of 3% (σ/2 Avg) or less.

The diameter D2 of the second region 61b is substantially the same as that of the wafer W. Namely, the boundary between the second region 61b and the third region 61c corresponds to the outer circumference of the wafer W supported on the susceptor 2. As a consequence, the plasma of nitrogen gas (active nitrogen) can be uniformly distributed over the second region 61b, so that the uniformity of distribution of the plasma of nitrogen gas (active nitrogen) on the entire wafer W can be further improved. In case the diameter of the wafer W is set to 1, the diameter of the through hole forming region 61 is set to range from about 1.1 to 2.0, and preferably from about 1.1 to 1.5. With this, the nitrogen can be more uniformly introduced into the wafer W.

When the wafer W has a diameter of about 300 mm, a diameter of the through holes 62a in the first region 61a is set to range from about 7 to 11 mm; that of the through holes 62b in the second region 61b is set to range from about 7 to 11 mm; and that of the through holes 62c in the third region 61c is set to range from about 9 to 13 mm. Further, the diameter D1 of the first region 61a is set to range from about 80 to 190 mm; the diameter D2 of the second region 61b is set to range from about 250 to 450 mm; and the diameter D3 of the third region 61c is set to range from about 400 to 650 mm. With this, it is possible to maintain the good uniformity in the processing using the plasma of nitrogen gas (active nitrogen).

The good uniformity in the processing using the plasma of nitrogen gas (active nitrogen) can be also maintained by setting the opening ratios of the through holes, instead of by setting the diameters of the through holes. Here, the opening ratio of the through holes 62a in the first region 61a is set to range from about 25 to 55%; the opening ratio of the through holes 62b in the second region 61b is set to range from about 30 to 65%; and the opening ratio of the through holes 62c in the third region 61c is set to range from about 50 to 80%.

The following is a description of a test showing the effects of the embodiment of the present invention.

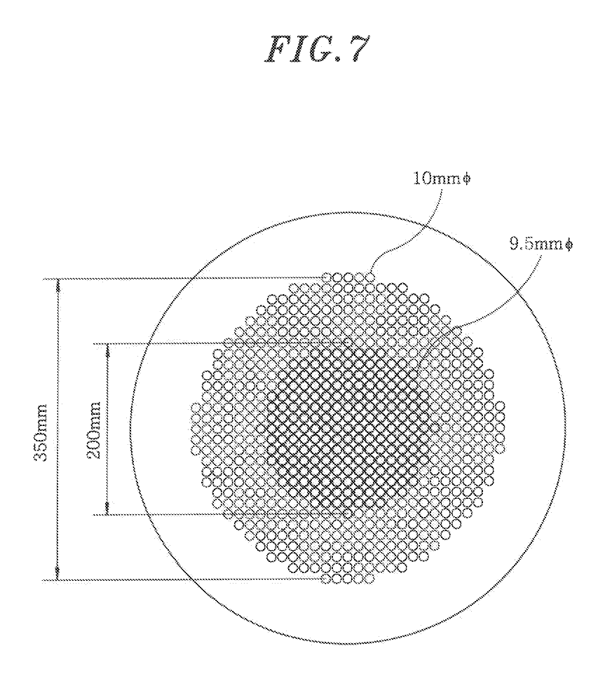

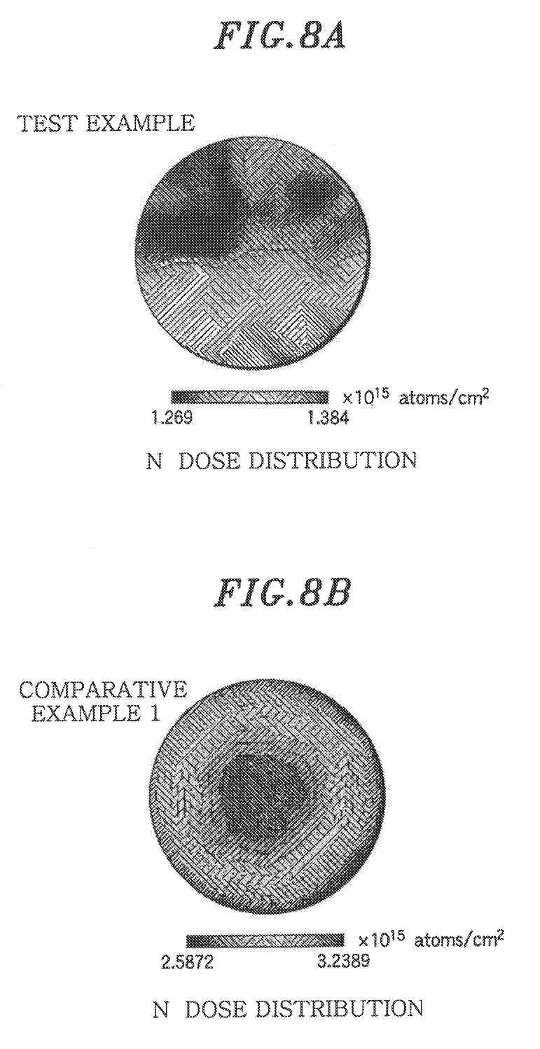

FIGS. 4 and 5 illustrate a gas through plate in accordance with the embodiment of the present invention (Test Example). In this gas through plate, a diameter of the through holes 62a in the first region 61a was about 9.5 mm; that of the through holes 62b in the second region 61b was about 9.7 mm; and that of the through holes 62c in the third region 6′1c was about 11 mm. The through holes were formed with a pitch of about 12.5 mm (opening ratio of the through holes 62a of the first region 61a: about 53.3%, opening ratio of the through holes 62b of the second region 61b: about 47.2%, opening ratio of the through holes 62c of the third region 61c: 60.7%). Further, a diameter D1 of the first region 61a was about 125 mm; a diameter D2 of the second region 61b was about 300 mm; and a diameter D3 of the third region 61c was about 425 mm. Further, in a gas through plate shown in FIG. 6 (Comparative Example 1), a diameter of a through hole forming region was about 350 mm, and through holes having a diameter of about 10 mm were uniformly formed with a pitch of about 12.5 mm (opening ratio of about 50.24%). In a gas through plate depicted in FIG. 7 (Comparative Example 2), a diameter of a through hole forming region was about 350 mm. Moreover, through holes having a diameter of about 9.5 mm were formed with a pitch of about 12.5 mm in a central portion having a diameter of about 200 mm (opening ratio of about 45.3%), and through holes having a diameter of about 10 mm were formed with a pitch of about 12.5 mm in a peripheral portion (opening ratio of 50.24%). Each of the through plates in FIGS. 4 to 7 was applied in a nitridation process which was performed on an oxide film formed on a wafer having a diameter of about 300 mm. Then, in-plane uniformity of the N dose of 1×10¹⁵/cm² (N concentration: 12 atomic %) (detected by XPS) was observed. The nitridation process was carried out under following conditions: a distance of about 30 mm between the gas through plate and the wafer; a pressure in the chamber set at about 6.7 Pa; an Ar gas having a flow rate of about 1000 mL/min; an N₂ gas having a flow rate of about 40 mL/min; a microwave power of about 1500 W; and a temperature controlled at about 400° C. The oxide films on the wafer W were respectively formed with a thickness of about 1.2 nm and about 1.6 nm of two cases by a thermal CVD process using a WVG (Water Vapor Generator).

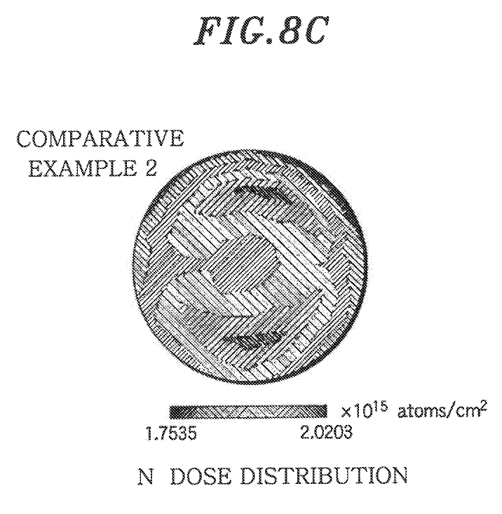

The results are shown in FIGS. 8A to 8C. As illustrated in FIG. 8B, in the Comparative Example 1, the N dose in the central portion is extremely high, which indicates poor uniformity. In the Comparative Example 2, although the N dose in the central portion is low, the N dose in parts of the peripheral portion is high, as depicted in FIG. 8C. That is, the uniformity is not good enough. In the Test Example, however, the uniformity is good over the entire region, as can be seen from FIG. 8A.

The uniformity of the N dose was measured as numerical values. As a result, the average of 1σ of the N dose in the Comparative Example 1 was about 7.9% and that in the Comparative Example 2 was about 4.2%. Meanwhile, the average of 1σ of the N dose in the Test Example was about 2.4%, which proves that the uniformity of the N dose has been greatly improved and also satisfies a required value of about 3.0 or less. From the above, it was clear that the uniformity in the plasma processing was higher in the Test example than in the Comparative Examples 1 and 2.

It is possible to introduce N into the oxide film at a low N dose of 20 atomic % or less with a uniformity of 3% (1σ). Especially, a low N dose of 10 atomic % or less is effective.

The present invention can be variously modified without being limited to the above embodiments. For example, a semiconductor wafer, especially a wafer having a diameter of about 300 mm, was used as a substrate in the above embodiments. However, a substrate is not limited thereto, but may be a semiconductor wafer having a diameter greater than or equal to about 200 mm. Further, a substrate may not be limited to a semiconductor wafer, but can be a substrate for use in an FPD (flat panel display) and the like, the substrate being represented by a glass substrate used for manufacturing an LCD (liquid display device). Moreover, an RLSA type plasma processing apparatus has been exemplified in the above embodiments. However, the plasma processing apparatus is not limited thereto, but may be, e.g., an ICP plasma processing apparatus, an ECR plasma processing apparatus, a surface reflected wave plasma processing apparatus, a magnetron plasma processing apparatus, a capacitively coupled plasma processing apparatus or the like.

In other words, it is more effective to uniformly introduce N into the oxide film from a plasma source of a high electron temperature while causing a low damage.

In addition, although a nitridation process has been exemplified in the above embodiments, the present invention is not limited thereto but can be applied to an oxidation process or another plasma process such as a film forming process, an etching process and the like. However, the present invention is suitable for a nitridation process, especially for nitridation of an ultra-thin film (oxide film). In that case, the device characteristics such as threshold voltage, boron punch through, ion characteristics can be improved by piling up N on the surface within 0.5 nm without diffusing N to an interface of the ultra-thin film and the substrate. The above effects are evident when the present invention is applied to nitridation of a gate oxide film especially having a thickness of about 2.5 nm or less.

### INDUSTRIAL APPLICABILITY

The plasma processing apparatus in accordance with the present invention is suitable for a nitridation process or an oxidation process of a semiconductor substrate.

What is claimed is:

1. A plasma processing apparatus comprising:
an evacuable vacuum processing chamber for processing a target substrate;
a process gas introducing mechanism for introducing a process gas into the processing chamber;
a plasma generating mechanism for generating a plasma of the process gas in the processing chamber;
a substrate supporting table for supporting the target substrate in the processing chamber; and
a gas through plate, provided between a plasma generating section and the substrate supporting table in the processing chamber, having a plurality of through holes for passing the plasma of the process gas therethrough,
wherein in the gas through plate, a through hole forming region in which the through holes are formed includes a region corresponding to the target substrate on the substrate supporting table and an external region thereof,
and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of regions having through holes of a different diameter,
and wherein the through holes in the first region have a smallest diameter while the through holes in the third region have a largest diameter.

2. The plasma processing apparatus of claim 1, wherein a distance between the substrate supporting table and the gas through plate is in a range of from 3 to 20 mm, and a ratio of an opening ratio of the through holes in the first region, that of the through holes in the second region and that of the through holes in the third region is 1:1-2.6:1.1-3.2.

3. The plasma processing apparatus of claim 1, wherein a boundary between the second region and the third region corresponds to an outer periphery of the target substrate supported on the substrate supporting table.

4. The plasma processing apparatus of claim 1, wherein when a diameter of the target substrate is set to 1, a diameter of the through hole forming region ranges from about 1.1 to 2.0.

5. The plasma processing apparatus of claim 1, wherein the plasma generating mechanism includes a microwave generating source; a planar antenna provided at a top portion of the processing chamber for radiating a microwave into the processing chamber; and a waveguide for transmitting the microwave from the microwave generating source to the planar antenna.

6. The plasma processing apparatus of claim 1, wherein N concentration of 20 atomic % or less is introduced into an oxide film with a uniformity of 3% or less (1σ).

7. The plasma processing apparatus of claim 1, wherein the gas through plate is made of a high purity quartz having impurities of about 50 ppm or less.

8. A plasma processing apparatus comprising:
an evacuable vacuum processing chamber for processing a target substrate;
a process gas introduction mechanism for introducing a process gas into the processing chamber;
a plasma generating mechanism for generating a plasma of the process gas in the processing chamber;
a substrate supporting table for supporting the target substrate in the processing chamber; and
a gas through plate, provided between a plasma generating section and the substrate supporting table in the processing chamber, having a plurality of through holes for passing the plasma of the process gas therethrough,
wherein in the gas through plate, a through hole forming region in which the through holes are formed includes a region corresponding to the target substrate on the substrate supporting table and an external region thereof,
and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of the regions having the through holes of a different opening ratio,
and wherein the through holes in the first region have a smallest opening ratio while the through holes in the third region have a largest opening ratio.

9. The plasma processing apparatus of claim 8, wherein a distance between the substrate supporting table and the gas through plate is in a range of from 3 to 20 mm, and the opening ratio of the through holes in the first region ranges from about 25 to 55%; the opening ratio of the through holes in the second region ranges from about 30 to 65%; and the opening ratio of the through holes in the third region ranges from about 50 to 80%.

10. The plasma processing apparatus of claim 8, wherein a boundary between the second region and the third region corresponds to an outer periphery of the target substrate supported on the substrate supporting table.

11. The plasma processing apparatus of claim 8, wherein when a diameter of the target substrate is set to 1, a diameter of the through hole forming region ranges from about 1.1 to 2.0.

12. The plasma processing apparatus of claim 8, wherein the plasma generating mechanism includes a microwave generating source; a planar antenna provided at an upper portion of the processing chamber, for radiating a microwave into the processing chamber; and a waveguide for transmitting the microwave from the microwave generating source to the planar antenna.

13. The plasma processing apparatus of claim 8, wherein N concentration of 20 atomic % or less is introduced into an oxide film with a uniformity of 3% or less (1σ).

14. The plasma processing apparatus of claim 8, wherein the gas through plate is made of a high purity quartz having impurities of about 50 ppm or less.

15. A gas through plate having a plurality of through holes for passing a plasma of a process gas therethrough, the gas through plate being provided between a plasma generating section and a substrate supporting table in a processing chamber of a plasma processing apparatus that performs a plasma processing on a target substrate supported on the substrate supporting table by using the plasma of the process gas generated in the processing chamber,
wherein a through hole forming region in which the through holes are formed includes a region corresponding to the target substrate on the substrate supporting table and an external region thereof,
and wherein the through hole forming region is provided with a first region corresponding to a central portion of the target substrate; a second region arranged on an outer circumference of the first region to correspond to a peripheral portion of the target substrate; and a third region arranged on an outer circumference of the second region to include the external portion of the target substrate, each of the regions having the through holes of a different opening ratio,
and wherein the through holes in the first region have a smallest opening ratio while the through holes in the third region have a largest opening ratio.

16. The gas through plate of claim 15, wherein a distance between the substrate supporting table and the gas through plate is in a range of from 3 to 20 mm, and the opening ratio of the through holes in the first region ranges from about 25 to 55%; the opening ratio of the through holes in the second region ranges from about 30 to 65%; and the opening ratio of the through holes in the third region ranges from about 50 to 80%.

17. The gas through plate of claim 15, wherein a boundary between the second region and the third region corresponds to an outer periphery of the target substrate supported on the substrate supporting table.

18. The gas through plate of claim 15, wherein when a diameter of the target substrate is set to 1, a diameter of the through hole forming region ranges from about 1.1 to 2.0.

19. The plasma processing apparatus of claim 15, wherein N concentration of 20 atomic % or less is introduced into an oxide film with a uniformity of 3% or less (1σ).

20. The plasma processing apparatus of claim 15, wherein the gas through plate is made of a high purity quartz having impurities of about 50 ppm or less.
